(19) United States
(12) Patent Application Publication
(10) Pub. No.: US 2014/0101500 A1
(43) Pub. Date: Apr. 10, 2014

(54) CIRCUITS AND METHODS FOR FUNCTIONAL TESTING OF INTEGRATED CIRCUIT CHIPS

(71) Applicant: LSI CORPORATION, Milpitas, CA (US)

(72) Inventors: Sachin Shivanand Bastimane, Pune (IN); Komal N. Shah, Mumbai (IN); Ramesh C. Tekumall, Breinigsville, PA (US); Allentown Madhani, Allentown, PA (US)

(73) Assignee: LSI Corporation, Milpitas, CA (US)

(21) Appl. No.: 13/645,873

(22) Filed: Oct. 5, 2012

(51) Int. Cl. G01R 31/3177

(52) U.S. Cl. 714/727; 714/729; 714/E11.155

(57) ABSTRACT

Circuits and methods are provided for debugging an integrated circuit. An integrated circuit includes core circuitry, scan test circuitry, scan control circuitry, and debug control circuitry. The scan test circuitry includes scan chains with scan cells interspersed throughout the core circuitry. The scan control circuitry controls the scan test circuitry to scan test the core circuitry. The debug control circuitry utilizes the scan test circuitry and controls the scan control circuitry to debug failure conditions of the integrated circuit during normal use. The scan control circuitry applies a debug clock signal to a clock port of each scan cell of a given scan chain to store data values that are generated by the core circuitry into the scan cells. The scan control circuitry controls the scan test circuitry to scan shift out the stored data values generated by the core circuitry during the debug process.

### BACKGROUND

In design for testability (DFT) applications, integrated circuits are often designed with scan test circuitry that is used during chip manufacturing to test for various internal fault conditions of an integrated circuit. Scan test circuitry typically comprises scan chains comprising multiple scan cells (registers), which are used to gain access to internal nodes of the integrated circuit. The scan cells may be implemented using a series of flip-flops or latches. The scan cells of a given scan chain are configurable to form a serial shift register for shifting in test patterns at inputs to combinational logic of the integrated circuit. The scan cells of the given scan chain are also used to capture outputs from other combinational logic of the integrated circuit. In this regard, scan testing of an integrated circuit may be viewed as being performed in two repeating phases, namely, a scan shift phase in which the scan cells of a scan chain are configured as a serial shift register for shifting in and shifting out of respective input and output scan data, and a scan capture phase in which the scan cells of the scan chain capture scan data from combinational logic. The captured data is subsequently shifted out to compare to expected patterns. These repeating scan test phases are often collectively referred to as a scan test mode of operation of the integrated circuit.

With regard to SoC (System-on-Chip) designs, when an SoC design development is complete, SoC bring up and debug processes are critical for successful operation in the field. In general, a debug process is time consuming and arduous, and internal SoC failures are hard to debug due to the limited ability to observe the state of internal registers inside an SoC. In order to debug failures in an SoC, however, chip designers need access to the state of the internal registers of the SoC. A debug test protocol for obtaining the internal register data state from an SoC should be simple. Moreover, this process should not add overhead to the SoC design in terms of area, routing congestion, and timing, for example.

### SUMMARY

Embodiments of the invention generally include circuits and methods for functional testing and debugging of an integrated circuit such as a system-on-chip. For example, in one embodiment, an integrated circuit includes core circuitry, scan test circuitry, scan control circuitry, and debug control circuitry. The scan test circuitry includes one or more scan chains, where each scan chain includes a plurality of scan cells interspersed throughout regions of the core circuitry. The scan control circuitry is configured to utilize the scan test circuitry to scan test the core circuitry. The debug control circuitry is configured to utilize the scan test circuitry and control the scan control circuitry to implement a debug mode of operation to debug failure conditions of the core circuitry during normal use of the integrated circuit. A debug control scheme can be implemented using a Joint Test Action Group (JTAG) protocol, for example.

In another embodiment of the invention, a method is provided for debugging the integrated circuit to debug failure conditions of the core circuitry during normal use of the integrated circuit. The debug process includes utilizing the scan control circuitry to selectively apply a debug clock signal to a clock port of each scan cell of a given scan chain during the debug process to store data values that are generated by the core circuitry into the scan cells during the debug process, and controlling the scan control circuitry to perform a scan shift operation using the scan test circuitry to scan shift out the stored data values generated by the core circuitry during the debug process. A debug process allows failure conditions to be re-created and logic changes to be made core circuitry of the integrated circuit so that internal signals of the integrated circuit can be readily observed for verification.

Embodiments of the invention will be described or become apparent from the following detailed description of embodiments, which is to be read in connection with the accompanying drawings.

### BRIEF DESCRIPTION OF THE DRAWINGS

FIG. 1 is a block diagram showing an integrated circuit testing system according to an embodiment of the invention.

FIG. 2 is a block diagram of an integrated circuit architecture comprising debugging control circuitry according to an embodiment of the invention.

FIG. 3 is a flow diagram of a debugging process according to an embodiment of the invention.

FIG. 4 is a high-level block diagram of a computing system for designing an integrated circuit of the type illustrated in FIG. 2, according to an embodiment of the invention.

### DETAILED DESCRIPTION

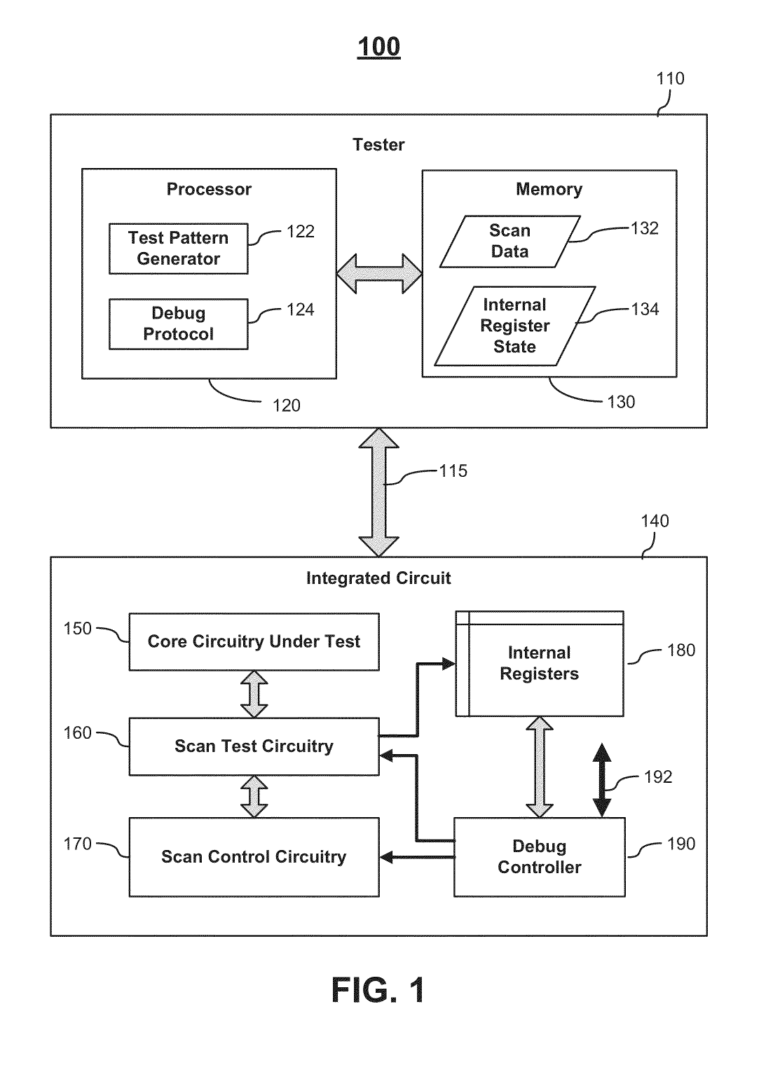

Embodiments of the invention will now be discussed in further detail below with regard to circuits and methods for functional testing and debugging of integrated circuits. FIG. 1 is a block diagram showing an integrated circuit testing system according to an embodiment of the invention. In particular, FIG. 1 shows an integrated circuit testing system 100 comprising a tester 110 and an integrated circuit 140 that is coupled to the tester 110 via an interface 115. In general, the tester 110 comprises a processor 120 and a memory 130. The processor 120 implements a test pattern generator 122 and a debug protocol 124 to perform various forms of scan testing, functional mode testing and debugging of an integrated circuit. The memory 130 stores various types of data such as scan data 132 and internal register state data 134, which is accessed from the integrated circuit 140 when the integrated circuit 140 is scan tested or debugged using the tester 110. In an embodiment, the test pattern generator 122 and debug protocol module 124 are modules that are instantiated as executing program code within the processor 120. In an alternate embodiment, the test pattern generator 122 and debug protocol module 124 are implemented using dedicated logic circuits and firmware, which are part of a special purpose processor designed with the special purpose hardware and/or firmware to perform scan testing and debugging functions.

As further shown in FIG. 1, the integrated circuit 140 comprises core circuitry 150, scan test circuitry 160, scan control circuitry 170, internal registers 180, a debug controller 190 and a debug controller interface 192. In general, the scan test circuitry 160 is coupled to the internal core circuitry 150 for scan testing the internal core circuitry (e.g., memory blocks, other combinatorial logic circuits, etc.) using the scan test circuitry 160. In an embodiment, the scan test circuitry 160 comprises a plurality of scan chains comprising multiple scan cells, and other types of test circuitry that is commonly used for performing scan testing of core circuit blocks of integrated circuits. In general, the scan control circuitry 170 includes various forms of control and multiplexer circuitry to apply clock signals and control signals to the scan test circuitry 160 for implementing a scan test protocol and other test modes of operation (e.g., built-in-self-test (BIST), memory built-in-self-test (MBIST), etc.) using test patterns generated by the test pattern generator 122 of the tester 110. The scan test data generated by the scan test circuitry 160 can be accessed by the tester 110 via the interface 115 and stored in the tester memory 130 as scan data 132.

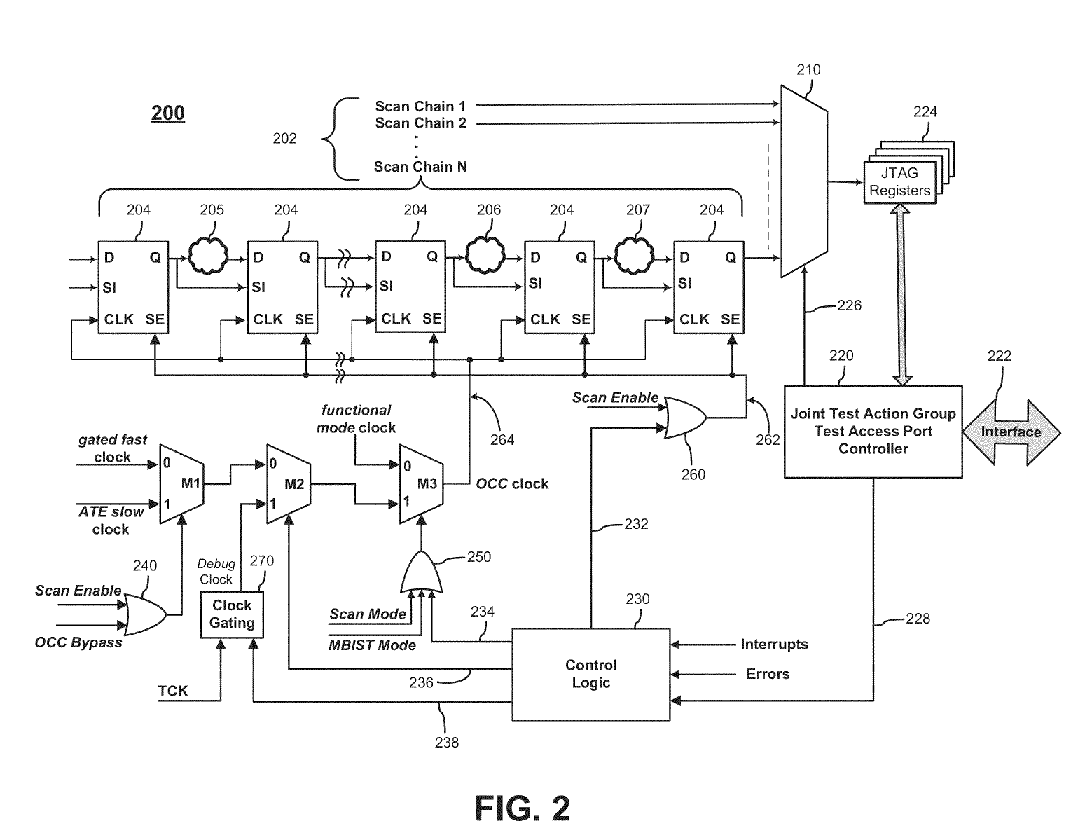

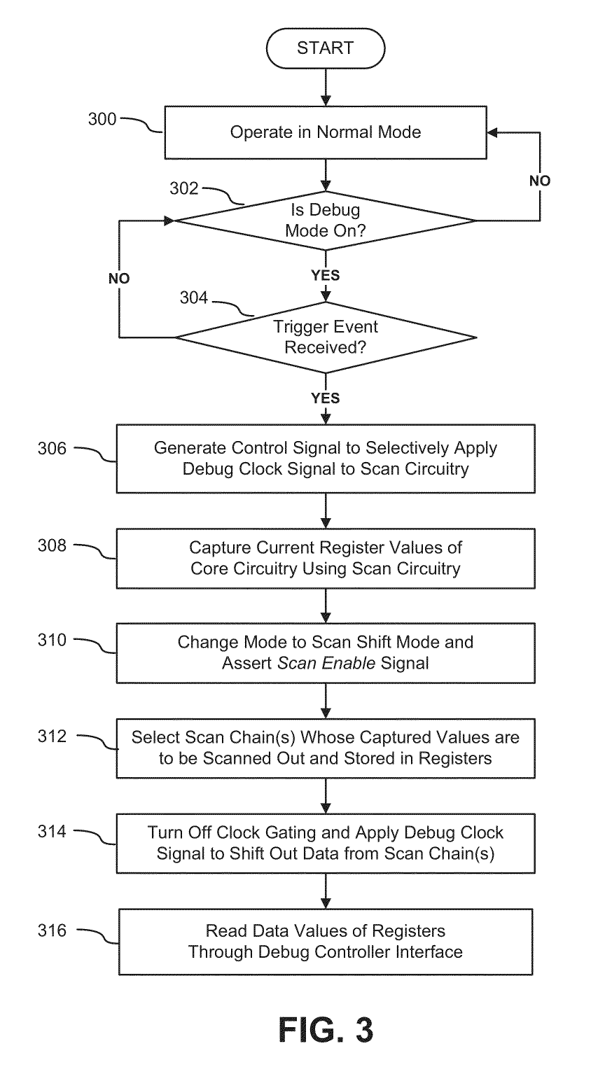

Furthermore, in an embodiment of the invention, debugging of failure conditions and errors of the integrated circuit 140 can be implemented using the internal registers 180, the debug controller 190, and the debug controller interface 192, in conjunction with the scan test circuitry 160 and the scan control circuitry 170 to verify operability of the integrated circuit 140 during actual use. In accordance with embodiments of the invention as discussed in further detail below with reference to FIGS. 2 and 3, for example, the scan test circuitry 160 and scan control circuitry 170 (which is used for performing standard scan testing, BIST testing and functional mode testing operations) is augmented with additional control logic and circuitry to support execution of a debug protocol 124 (initiated via the tester 110) that enables debugging of failure conditions and operating errors of the integrated circuit 140.

In an embodiment, a debug process (which is implemented via the debug protocol 124) provides various debug test signals such as debug test clocks and control signals, as well as debug test data to the integrated circuit 140. The debug test signals and test data are input to the debug controller 190 via the debug controller interface 192. The debug controller 190 uses these signals in conjunction with the scan control circuitry 170 to operate the scan test circuitry 160 and perform a debug process on the core circuitry 150, and store the results of the debug process in the internal registers 180. The internal state of the registers 180 is accessed by the debug controller 190 and output (via an output port of the interface 192) to the tester 110 over the interface 115, wherein the debug test output data can be stored as the internal register state data 134 in the memory 130 of the tester 110. In an embodiment, the debug protocol 124 and debug controller 190 are implemented using a JTAG scheme, although in alternate embodiments of the invention, other standard or non-standard debugging protocols may be used to implement debugging techniques based on techniques as described herein.

It is to be noted that the tester 110 in the testing system 100 of FIG. 1 need not take any particular form, and various conventional testing system arrangements may be implemented to support debugging and testing of an integrated circuit using techniques described herein. For example, in an embodiment, the tester 110 is a load board on which the integrated circuit 140 to be tested is mounted or otherwise installed. In other embodiments, at least a portion of the tester 110, such as the test pattern generator 122 or debug protocol 124, is incorporated into the integrated circuit 140. In an alternate embodiment, the entire tester 110 is incorporated into the integrated circuit 140. In other embodiments, the testing system 100 includes other elements in addition to or in place of those specifically shown, including one or more elements of a type commonly found in a conventional implementation of such a system. For example, various elements of the tester 110 or other parts of the system 100 may be implemented, by way of illustration only and without limitation, utilizing a microprocessor, central processing unit (CPU), digital signal processor (DSP), application-specific integrated circuit (ASIC), field-programmable gate array (FPGA), or other type of data processing device, as well as portions or combinations of these and other devices.

In an embodiment, the integrated circuit 140 is configured for installation on a circuit board or other mounting structure in a computer, server, mobile telephone or other type of communication device. Such communication devices may also be viewed as examples of what are more generally referred to herein as “processing devices.” The term “processing devices” is also intended to encompass storage devices, as well as other types of devices comprising data processing circuitry.

FIG. 2 is a block diagram of an integrated circuit architecture comprising debugging control circuitry according to an embodiment of the invention. In particular, FIG. 2 shows an embodiment of an integrated circuit 200 (or SoC) having an architecture that is based on the general framework of the integrated circuit 140 shown in FIG. 1 in which a debugging scheme is implemented using a JTAG scheme. In general, the integrated circuit 200 comprises a plurality of scan chains 202 (scan chain 1, . . . , scan chain N), a scan output multiplexer 210, a JTAG TAP (test access port) controller 220, a JTAG interface 222, a plurality of JTAG user defined registers 224, a control logic block 230, a first OR gate 240, a second OR gate 250, a third OR gate 260, a clock gating circuit 270, and a plurality of clock signal select multiplexers M1, M2 and M3.

Each of the scan chains 202 comprises a plurality of scan cells 204 that are interspersed with various circuit blocks of a core circuit that is under test. For instance, FIG. 2 shows an embodiment of one scan chain 202 (e.g., scan chain N), which comprises a series of scan cells 204. Each scan cell 204 comprises a data (D) input port, a scan input (SI) port, a data (Q) output port, a clock (CLK) input port, and scan enable (SE) control port. The number N of scan chains 202 that are used for a given integrated circuit will vary depending on the type of integrated circuit to be tested and the target test applications. Moreover, the number of scan cells 204 in each scan chain 202 will also vary depending on the type of integrated circuit to be tested and the target test applications. For example, in an embodiment, the integrated circuit 200 can have N=19 scan chains 202, wherein each scan chain 202 comprises 12,000 scan cells 204. In some embodiments of the invention, the lengths of the scan chains 202 are balanced (i.e., having the same number of scan cells 204) so that the same amount of time is needed to shift a desired set of scan test patterns into each scan chain 202.

In the embodiment of FIG. 2, the core circuitry under test comprises a plurality of circuit blocks (e.g., blocks 205, 206 and 207) that are disposed between adjacent scan cells 204. The circuit blocks 205, 206 and 207 comprise any type of circuit that can be tested utilizing the scan test and debugging circuitry in embodiments of the invention. By way of example, the circuit blocks 205, 206 and 207 represent different and/or repeated portions of a SoC integrated circuit in a hard disk drive (HDD) controller application, designed for reading and writing data from one or more magnetic storage disks of an HDD. In other embodiments, the circuit blocks 206, 206 and 207 comprise other types of functional logic circuitry or combinatorial logic blocks, depending on the architecture and function of the integrated circuit.

In the embodiment of FIG. 2, the circuit blocks 205, 206, and 207 are arranged between the Q output port of one scan cell 204 and the D input port of an adjacent downstream scan cell 204 in the scan chain N. Moreover, the Q output port of one scan cell 204 is connected to the SI port of an adjacent downstream scan cell 204 in the scan chain N. The Q output port of the last scan cell 204 in each of the scan chains 202 is connected to a given input of the scan output multiplexer 210.

In the embodiment of FIG. 2, the plurality of scan chains 202 and circuit blocks 205, 206 and 207 represent an exemplary embodiment of the core circuitry 150 and scan test circuitry 160 shown in FIG. 1. Moreover, the scan output multiplexer 210, the control logic block 230, the OR gates 240, 250, and 260, the clock gating circuit 270, and the clock signal select multiplexers M1, M2 and M3 represent an exemplary embodiment of the scan control circuitry 170 shown in FIG. 1. Further, the JTAG TAP controller 220 and JTAG interface 222 represent an exemplary embodiment of the debug controller 190 and interface 192, respectively, shown in FIG. 1. Moreover, the JTAG user defined registers 224 represent an exemplary embodiment of the internal registers 180 shown in FIG. 1. The JTAG interface 222 provides a multi-signal TAP to enable input/out of signals, including a test clock (TCK) port, a test mode select (TMS) signal port, test data input (TDI), and test data output (TDO), wherein the TDI and TDO are serial interface ports. A JTAG debug test can be implemented to verify operability of the core circuitry (e.g., blocks 205, 206 and 207) by operating the scan test and control circuitry in response to sequence of control signals applied a the TMS interface port of the JTAG TAP controller 220.

The scan output multiplexer 210 has N inputs, wherein each of the N inputs is connected to the Q output port of a last scan cell 204 in a corresponding one of the plurality of scan chains 202. The scan output multiplexer 210 is controlled by a control signal applied on control line 226 from the JTAG TAP controller 220. The output of the scan output multiplexer 210 is connected to the JTAG user defined registers 224. The control signal applied on the control line 226 from the JTAG TAP controller 220 selects one of the scan chains 202 for outputting data of the selected scan chain 202 for storage in the JTAG user defined registers 224.

The control logic block 230 receives control signals from the JTAG TAP controller 220 via a control line 228. The control logic block 230 receives “debug mode” triggering events, such as error events and interrupt events (internal or external interrupts). The control signals applied on control line 228 serve to program the control logic block 230 for various functions. For example, a control signal may be applied on control line 228 to select which interrupt to be used for triggering a debug process. A control signal may be applied on control line 228 to program user-defined “wait” states that specify a time for waiting to trigger a debug process after receiving an error. A control signal may be applied on the control line 228 to program the control logic block 230 to recognize a sequence of events (errors) that causes the triggering of a debug process. In other embodiments, control signals may be applied on the control line 228 to specify a number of clock pulses to be generated through the OCC (on chip clock) logic for a debug process, and to enable access to programmable registers of the control logic block 230.

In accordance with embodiments of the invention, the scan test and control circuitry in FIG. 2 can operate in one of various test modes including a scan mode, a functional mode, and a memory built-in-self-test (MBIST) mode, for example. Moreover, the scan test and control circuitry in FIG. 2 can operate in conjunction with the JTAG TAP controller 220 to operate in a debugging mode to verify operability of the core circuitry of the integrated circuit 200. For example, for scan mode, functional mode, and MBIST mode testing, an OCC controller scheme multiplexes between an automated test equipment slow (ATE slow) clock (which is used for shift and slow capture), a gated fast clock (which is used for at speed testing), and a functional mode clock. For a debug mode of operation, the control logic block 230 generates various control signals including, for example, (i) a control signal that is applied to an input of the OR gate 260 via control line 232, (ii) a control signal that is applied to an input of the OR gate 250 via control line 234, (iii) a control signal that is applied to a select control port of the clock signal select multiplexer M2 via control line 236, and (iv) a control signal that is applied to the clock gating block 270 via control line 238.

As shown in FIG. 2, a gated fast clock signal and an ATE slow clock signal are applied to inputs of the clock signal select multiplexer M1. A Scan Enable control signal and an OCC Bypass control signal are applied to inputs of the OR gate 240. An output of the OR gate 240 is connected to a select control port of the clock signal select multiplexer M1. If the Scan Enable control signal is asserted, or if there is a need to bypass the OCC circuit, the output of the OR gate 240 will be logic “1”, causing the clock signal select multiplexer M1 to select the ATE slow clock signal coming from the ATE. Otherwise, the clock signal select multiplexer M1 will select the gated fast clock signal that is required for “at speed” testing.

An output of the clock signal select multiplexer M1 in connected to one input of the clock signal select multiplexer M2, and an output of the clock gating block 270 is connected to another input of the clock signal select multiplexer M2. The clock gating block 270 selectively outputs a gated JTAG test clock signal (gated TCK) to an input of the clock signal select multiplexer M2 in response the control signal applied on the control line 238. More specifically, in a debug mode of operation, when a SCAN mode is not present, a gated TCK clock signal (which applied to an input of the clock signal select multiplexer M2) will be selected for output from the clock signal select multiplexer M2 in response to the assertion of a control signal applied to the select control port of the multiplexer M2 via the control line 236. The number of TCK clock pulses that are output from the clock gating block 270 to the input of the clock signal select multiplexer M2 is controlled by a control signal applied on the control line 238. In this regard, when the JTAG clock TCK is selected for shifting data out through a JTAG port of the interface 222 during a debug mode of operation, the control logic block 230 will generate a control signal on line 238 that specifies a number of TCK clock pulses to be applied to the scan logic so that the status of only the required registers will be shifted out from the JTAG interface 222.

An output of the clock signal select multiplexer M2 is connected to one input of the clock signal select multiplexer M3. A functional mode clock signal is applied to another input of the clock signal select multiplexer M3. A select control port of the clock signal select multiplexer M3 is connected to an output of the OR gate 250. The OR gate 250 receives a scan mode control signal, an MBIST mode control signal, and a debug mode control signal applied on the control line 234 from the control logic block 230. The OR gate 250 generates a control signal that is applied to the select control port of the clock signal select multiplexer M3 to selectively output a clock signal (OCC clock signal) on a clock signal line 264. The OCC clock signal is applied to the CLK port of each scan cell 204 via a clock signal line 264. The OCC clock signal at the output of the clock signal select multiplexer M3 will vary depending on the selected mode of operation, test mode or functional mode. In functional mode, the functional mode clock is output from the clock signal select multiplexer M3 as the OCC clock signal that is applied to the CLK port of each scan cell 204 via a clock signal line 264. In test mode, either the ATE slow clock (for scan testing) or the gated fast clock (for at speed testing) or gated JTAG clock TCK (for debug mode) will be output as the OCC clock signal that is applied to the CLK port of each scan cell 204 via a clock signal line 264. The functional debug mode, which is separate from the SCAN mode or MBIST mode, is initiated using a separate control signal that is applied on control line 234 from the control logic block 230 to select the gate JTAG clock TCK to drive to logic.

Moreover, in the scan control circuitry of FIG. 2, the OR circuit 260 receives as input a Scan Enable control signal and a control signal applied on the control line 232 from the control logic block 230 and outputs a scan shift control signal that is applied to the SE ports of the scan cells 204. The output of the OR gate 260 is connected to a clock signal line 262, which is connected to the SE port of each scan cell 204 in the scan chain 202. The Scan Enable signal is generated from DFT logic (not shown) to implement a standard scan mode of operation. In one embodiment, the Scan Enable signal is output as a scan shift control signal, wherein the scan cells 204 of the given scan chain 202 are configured to form a serial shift register in response to the Scan Enable signal being at a first designated logic level (e.g., a logic “1” level), and wherein the scan cells are configured to capture functional data when the Scan Enable signal is at a second designated logic level (e.g., a logic “0” level).

In functional debug mode, the standard SCAN mode will be off. However, to provide control of the SE ports of the scan cells 204 in a debug mode, when a trigger is asserted, the control logic block 230 generates a control signal on line 232 to operate the scan circuitry in a scan mode of operation by controlling the SE ports of the scan cells 204. A single SE signal is used to control all of the scan chains 204, or only a subset of the scan chains, with the remaining scan chains being controlled using one or more other SE signals. The SE signal in an embodiment controls configuration of scan cells of a scan chain to form a serial shift register for shifting in and shifting out of test patterns. The SE signal may therefore be considered a type of scan shift enable signal, or more generally, a type of scan shift control signal. Other types of scan shift control signals may be used in other embodiments.

In a scan mode, the clock signal select multiplexers M1, M2 and M3 are selectively controlled (via respective select control signals output from the OR gate 240, control logic block 230 and OR gate 250) to output the gated fast clock signal or the ATE slow clock signal to the clock signal line 264 at the output of the multiplexer M3. In a functional mode of operation, the clock signal select multiplexer M3 is selectively controlled via a select control signal output from the OR gate 250 to output the functional mode clock signal to the clock signal line 264 at the output of the multiplexer M3. Thus, in the exemplary framework of FIG. 2, the multiplexers M1 and M3 control the clock signal that is applied to the scan cell logic in the functional and scan/BIST modes.

Furthermore, in the exemplary framework of FIG. 2, in response to a triggering event such as an error or interrupt, the control logic block 230 switches from a functional mode to a debug mode and make sure that Scan Enable is driven appropriately. When a debug mode of operation is initiated, the multiplexers M2 and M3 are selectively controlled (via respective select control signals output from the control logic block 230 (on line 236) and the OR gate 250) to output the gated TCK clock signal to the clock signal line 264. In particular, when the control logic block 230 is triggered on an event such as error or interrupt condition (internal or external interrupt), the control logic block 230 takes control of the clock by selectively outputting the TCK clock (at the input of the multiplexer M2) to the clock signal line 264. The TCK clock drives the functional logic to latch a current status of the registers. In the debug mode, the control logic block 230 operates on a frequency of the functional mode clock signal so that correct values can be latched immediately after a failure condition. Each scan chain 202 will use the gated JTAG clock TCK (which is input to the CLK port of the scan cells 204) to shift out data.

Thereafter, by switching the logic to a scan shift mode, the current latched values of the registers 224 are driven out on the chip port through the JTAG interface 222. In particular, since the scan chains 202 are multiplexed for JTAG output, the status of the registers (from a failing scan chain) can be shifted out to the JTAG user defined registers 224. Once the data is stored in the JTAG user defined registers 224, the data can be read suing the JTAG interface 222. As the location of the scan cells 204 in the given scan chain 202 are known from the DFT tool, the output data can be mapped to internal registers which will give designer the condition at which the failure occurred.

During the debug mode, the scan cells 204 continuously capture functional signal values from respective circuit blocks 205, 206, 207. At a particular point in time, a debug mode signal, which is normally at a logic “1” level, transitions to a logic “0” level, the scan chain 202 is placed into its scan shift mode in order to shift out the latest captured signal values for observation. The scan cells 204 can be configured such that when the switch is made from the functional (debug) mode to the scan shift mode, the current contents of the scan cells 204 are preserved. This can be accomplished, for example, by configuring the scan cells to comprise respective non-resettable flip-flops and turning off their clocks in conjunction with the switch from functional mode to scan shift mode. The clock signal input to the CLK port of the scan cells 204 are then turned back on once the scan cells 204 are in scan shift mode in order to allow the captured contents to be shifted out for observation.

FIG. 3 is a flow diagram of a control method for performing a debugging process according to an embodiment of the invention. In particular, FIG. 3 illustrates a mode of operation of the test mode control circuitry of FIG. 2 according to an embodiment of the invention. Initially, while an integrated circuit is operating in a normal operating mode (step 300), a determination is made as to whether a debug mode of operation is initiated (step 302). In the embodiment of FIG. 2, a debug mode can be initiated by sending an external control signal to the JTAG TAP controller 220 via the interface 222, which, in turn, outputs a control signal (via control line 228) to the control logic block 230 to initiate a debug operating mode.

When the debug mode is initiated (affirmative determination in step 302), the control logic block 230 will wait for a triggering event (step 304). As noted above, a triggering event may be an error condition or an interrupt condition that is input to the control logic block 230. When a triggering event is received (affirmative result in step 304), the control logic block 230 will generate the appropriate control signals to selectively apply a debug clock signal to drive the scan circuitry (step 306). In one embodiment as shown in FIG. 2, this step involves switching the clock signal applied to the CLK port of the scan cells 204 from the functional mode clock signal to the gated TCK clock signal (debug clock signal) that is output from the clock gating block 270. Moreover, the control logic block 230 generates control signals on control lines 234, 236 and 238 to control the clock gating block 270 and multiplexer M2 and OR gate 250 to cause the debug clock signal to be output from the multiplexer M3 on the clock signal line 264. With the debug clock signal applied, the circuit blocks under test will be driven to capture a current status of the registers via the outputs of the various circuit blocks 205, 206 and 207 that are input to the D input ports of the scan cells 204 (step 308).

Next, the operating mode is changed to a scan shift mode and the Scan Enable signal is asserted (step 310). In the embodiment of FIG. 2, this mode change is performed by the control logic block 230 generating control signals on the control lines 232 to enable a scan mode, wherein the SE signal on the control line 262 will be “ON” (e.g., logic “1”). When a switch is made from the functional (debug) mode to the scan shift mode, the current contents of the scan cells 204 are preserved when the debug clock signal applied to the CLK ports of the scan cells 204 is turned off in conjunction with the switch from the functional debug mode to the scan shift mode. Furthermore, in this step, control signals are asserted control lines 234 and signal 236 so that the debug clock signal will be selected from the clock gating block 270.

After the mode is changed to scan shift mode, one of the scan chains 202 is selected whose captured values are to be scanned out and stored in the JTAG user defined registers 234 (step 312). In the embodiment of FIG. 2, a given one of the scan chains 202 is selected via a select control signal applied (vain control line 226) to the select control port of the output multiplexer 210 from the JTAG TAP controller 220.

Once a target scan chain is selected, the clock gating applied to the JTAG clock TCK signal (via clock gating block 270) is turned off so that the debug clock signal is applied to the CLK ports of the scan cells 204 to cause the captured contents to be shifted out from the scan cells 204 (of the selected scan chain 202) into the JTAG user defined registers 224 (step 314). In this step, a control signal is asserted on control line 238, which is a clock gating control signal for the JTAG clock TCK. This signal is asserted by default so that JTAG clock will be gated, once all the can cells 204 are in Scan mode, depending on a user programmable control register or length of the scan chain or number of the scan cells for which the status must be checked by passing the values to the registers. Once the required number of clock pulses reach the registers, the clock gating will be enabled again. Thereafter, the stored data values in the JTAG user defined registers 224 can be accessed for observation through the JTAG interface 222 via operation of the JTAG TAP controller 220 (step 316).

In the embodiments described herein, a debug process implements control logic that operates on a system clock so that there is less delay for latching status values in the registers. Therefore, with this process, more accurate debug data can be received. Moreover, since most of the scan cells 204 are included in the scan chains 202, a significantly large number of observable internal signals can be accessed. Furthermore, debug control schemes according to embodiments described herein do not require the use of large multiplexer logic circuits to access the internal register data, which would add to more area overhead and routing congestion to the integrated circuit.

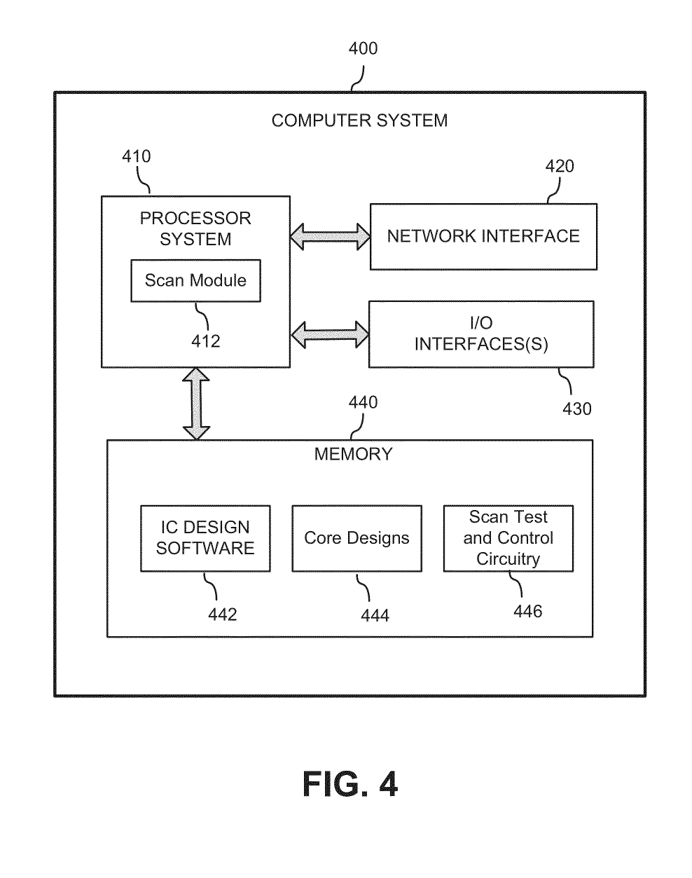

FIG. 4 is a high-level block diagram of a computing system 400 for designing an integrated circuit of the type illustrated in FIG. 2, according to an embodiment of the invention. In general, the computing system 400 comprises a processor system 410, a network interface 420, one or more input/output (I/O) interfaces 430, and a memory system 440 which stores, for example, IC design software 442 and stored program data representing circuits such as core circuit designs 444 and scan test and control circuitry 446 that are designed using the software 442.

The network interface 420 is coupled to the processor system 410 to provide an interface that allows the processor system 410 to communicate with other systems and devices over one or more networks. The network interface 420 may comprise one or more transceivers. The I/O interface(s) 430 is/are coupled to the processor system 410 to provide an interface that allows the processor system 410 to communicate with one or more external devices such as a keyboard, a pointing device, a display, etc. The processor system 410 is coupled to the memory 440 to execute program instructions (e.g., IC design software 442) and access associated data (e.g., component designs 444 and 446) for designing an integrated circuit.

For instance, the IC design software 442 includes one or more software programs for implementing an RTL design phase to convert a user specification of integrated circuit function into an RTL description, and to implement various phases of a physical design including, but not limited to, logic synthesis, placement, signal distribution network synthesis, routing and timing analysis, using known techniques, to generate circuit components 444 and 446 that are stored in memory 440. The processor 410 implements a scan module 412 for supplementing the core circuit designs 444 with scan test and control circuitry 446 configured for testing the core circuit designs 444 in conjunction with utilizing of the design software 442. The memory 440 is an example of what is more generally referred to herein as a computer readable storage medium or other type of computer program product having computer program code tangibly embodied thereon. The memory 440 may comprise, for example, electronic memory such as random access memory (RAM) or read only memory (ROM), magnetic memory, optical memory, or other types of storage devices in any combination. The processor system 410 may comprise a microprocessor, CPU, ASIC, FPGA, or other type of processing device, as well as portions or combinations of such devices.

Furthermore, as indicated above, embodiments of the invention are implemented in the form of integrated circuits such as shown in FIG. 2. In an integrated circuit implementation, identical dies are typically formed in a repeated pattern on a surface of a semiconductor wafer. Each die includes one or more circuit cores and circuitry as described herein, and may include other structures or circuits. The individual die are cut or diced from the wafer, and then each die is packaged as an integrated circuit. One skilled in the art would know how to dice wafers and package die to produce integrated circuits. Integrated circuits so manufactured are considered embodiments of this invention.

Although embodiments of the invention have been described herein with reference to the accompanying drawings, it is to be understood that embodiments of the invention are not limited to the described embodiments, and that various changes and modifications may be made by one skilled in the art resulting in other embodiments of the invention within the scope of the following claims.

What is claimed is:

1. An integrated circuit, comprising:
core circuitry;
scan test circuitry comprising one or more scan chains, wherein each scan chain comprises a plurality of scan cells interspersed throughout regions of the core circuitry;
scan control circuitry configured to utilize the scan test circuitry to scan test the core circuitry; and
debug control circuitry configured to utilize the scan test circuitry and control the scan control circuitry to implement a debug mode of operation to debug failure conditions of the core circuitry during normal use of the integrated circuit.

2. The integrated circuit of claim 1, wherein the scan test circuitry and the scan control circuitry are configured to perform scan shift testing or functional mode testing or both scan shift testing and functional mode testing.

3. The integrated circuit of claim 1, wherein the debug control circuitry comprises:
a debug controller for controlling a debug mode of operation;
a debug controller interface to enable access to the debug controller to input control signals and input data for performing a debug process;
a plurality of internal registers; and
an output multiplexer circuit connected to an output of each of the plurality of scan chains,
wherein the debug controller controls the output multiplexer circuit to switchably connect an output of a target scan chain to an output port of the output multiplexer circuit to store debug data, which is output from the target scan chain, into the internal registers.

4. The integrated circuit of claim 3, wherein the debug controller is configured to access the debug data from the internal registers and output the debug data to an external system using the debug controller interface.

5. The integrated circuit of claim 3, wherein the debug controller comprises a Joint Test Action Group Test Access Port controller and wherein the debug interface comprises a Joint Test Action Group Test Access Port interface.

6. The integrated circuit of claim 3, wherein the debug control circuitry further comprises a multiplexer circuit, incorporated as part of the scan control circuitry, to selectively apply a debug clock signal to a clock port of each scan cell of a given scan chain during a debug process to store data values that are generated by the core circuitry into the scan cells.

7. The integrated circuit of claim 6, wherein the debug control circuitry is configured to control the scan control circuitry to perform a scan shift operation using the scan test circuitry to scan shift out the stored data values generated by the core circuitry during the debug process.

8. The integrated circuit of claim 1, wherein a debug process is automatically triggered upon a triggering event, wherein the triggering event comprises an error condition or an interrupt.

9. A processing device comprising the integrated circuit of claim 1.

10. A method for debugging an integrated circuit which comprises core circuitry, scan test circuitry comprising one or more scan chains, wherein each scan chain comprises a plurality of scan cells interspersed throughout regions of the core circuitry, and scan control circuitry configured to utilize the scan test circuitry to scan test the core circuitry, the method comprising;
performing a debug process to debug failure conditions of the core circuitry during normal use of the integrated circuit, wherein performing a debug process comprises:
utilizing the scan control circuitry to selectively apply a debug clock signal to a clock port of each scan cell of a given scan chain during the debug process to store data values that are generated by the core circuitry into the scan cells during the debug process; and
controlling the scan control circuitry to perform a scan shift operation using the scan test circuitry to scan shift out the stored data values generated by the core circuitry during the debug process.

11. The method of claim 10, wherein the scan test circuitry and the scan control circuitry are configured to perform scan shift testing or functional mode testing or both scan shift testing and functional mode testing.

12. The method of claim 10, integrated circuit of claim 1, wherein performing a debug process comprises:
controlling a debug mode of operation using a debug controller that is separate from the scan control circuitry;
inputting control signals and input data to the debug controller to perform the debug process; and
switchably connecting an output of a target scan chain to internal registers to store debug data that is output from the target scan chain.

13. The method of claim 10, further comprising accessing the debug data from the internal registers and outputting the debug data to an external system using a debug controller interface.

14. The method of claim 10, wherein the debug process is implemented using a Joint Test Action Group protocol.

15. The method of claim 10, wherein performing a debug process further comprises selectively applying a debug clock signal to a clock port of each scan cell of a given scan chain during the debug process to store data values that are generated by the core circuitry into the scan cells of the given scan chain.

16. The method of claim 15, further comprising performing a scan shift operation using the scan test circuitry to scan shift out the stored data values generated by the core circuitry during the debug process.

17. The method of claim 10, further comprising automatically triggering the debug process upon a triggering event, wherein the triggering event comprises an error condition or an interrupt.

18. A computer-readable storage medium having computer program code embodied therein, wherein the computer program code is executable by a computer to perform the method of claim 10.

19. A computing system, comprising:
a memory to store program instructions, and data characterizing an integrated circuit design which comprises core circuitry, scan test circuitry comprising one or more scan chains, wherein each scan chain comprises a plurality of scan cells interspersed throughout regions of the core circuitry, and scan control circuitry configured to utilize the scan test circuitry to scan test the core circuitry; and
a processor system coupled to the memory, wherein the processor system is configured to execute the program instructions to perform a method for debugging the integrated circuit design, the method comprising:
performing a debug process to debug failure conditions of the core circuitry during a simulated normal use of the integrated circuit, wherein performing a debug process comprises:
utilizing the scan control circuitry to selectively apply a debug clock signal to a clock port of each scan cell of a given scan chain during the debug process to store data values that are generated by the core circuitry into the scan cells during the debug process; and
controlling the scan control circuitry to perform a scan shift operation using the scan test circuitry to scan shift out the stored data values generated by the core circuitry during the debug process.

20. The computing system of claim 19, wherein the debug process is implemented using a Joint Test Action Group protocol.
